(19) United States
(12) Patent Application Publication
(10) Pub. No.: US 2026/0106576 A1
(43) Pub. Date: Apr. 16, 2026

(54) IMPEDANCE ADJUSTMENT CIRCUIT AND AMPLIFIER CIRCUIT

(71) Applicant: RichWave Technology Corp., Taipei (TW)

(72) Inventor: Ting-Yuan Cheng, Taipei (TW)

(73) Assignee: RichWave Technology Corp., Taipei (TW)

(21) Appl. No.: 18/961,432

(22) Filed: Nov. 26, 2024

(30) Foreign Application Priority Data
Oct. 15, 2024 (TW) 113139215

(51) Int. Cl. H03F 1/56; H03F 3/213

(52) U.S. Cl. CPC H03F 1/56; H03F 3/213; H03F 2200/451

(57) ABSTRACT

An impedance adjustment circuit and an amplifier circuit are provided. The impedance adjustment circuit includes an input terminal, an output terminal, and an impedance adjustment sub-circuit. The impedance adjustment sub-circuit includes a metal-oxide-semiconductor capacitor (MOSCAP) and a switch circuit. A first terminal of the MOSCAP is coupled to the input terminal. A control terminal of the MOSCAP receives a control signal. A control terminal of the switch circuit receives a switch control signal. A base terminal of the MOSCAP is coupled to the output terminal. A capacitance value of the impedance adjustment sub-circuit is changed by changing the switch control signal.

### CROSS-REFERENCE TO RELATED APPLICATION

This application claims the priority benefit of Taiwan application serial no. 113139215, filed on Oct. 15, 2024. The entirety of the above-mentioned patent application is hereby incorporated by reference herein and made a part of this specification.

### BACKGROUND

### Technical Field

The invention relates to a signal processing technology in electronic circuits, and particularly relates to an impedance adjustment circuit and an amplifier circuit.

### Description of Related Art

Amplifier circuits are used in many technical fields, such as radio frequency (RF) application technology, signal processing technology, etc. An input terminal or an output terminal of an amplifier circuit may be configured with an impedance matching device or a corresponding matching circuit to reduce noise of an input signal of the amplifier circuit, and it is expected to reduce loss of an amplified signal and increase its gain.

### SUMMARY

An embodiment of the invention provides an impedance adjustment circuit for providing different capacitance values. The impedance adjustment circuit includes an input terminal, an output terminal, and an impedance adjustment sub-circuit. The impedance adjustment sub-circuit includes a metal-oxide-semiconductor capacitor (MOSCAP) and a switch circuit. The MOSCAP includes a first terminal, a second terminal, a control terminal, and a base terminal, wherein the first terminal is coupled to the input terminal, and the control terminal of the MOSCAP receives a control signal. The control terminal of the switch circuit receives a switch control signal. The base terminal of the MOSCAP is coupled to the output terminal through the switch circuit, wherein a capacitance value of the impedance adjustment sub-circuit is changed by changing the switch control signal.

An embodiment of the invention provides an impedance adjustment circuit for providing different capacitance values. The impedance adjustment circuit includes an input terminal, an output terminal, and an impedance adjustment sub-circuit. The impedance adjustment sub-circuit includes a metal-oxide-semiconductor capacitor (MOSCAP) and a switch circuit. The MOSCAP includes a first terminal, a second terminal, a control terminal, and a base terminal, wherein the control terminal of the MOSCAP is coupled to the input terminal. A control terminal of the switch circuit receives a switch control signal, and the base terminal of the MOSCAP is coupled to the output terminal through the switch circuit, wherein a capacitance value of the impedance adjustment sub-circuit is changed by changing the switch control signal.

The amplifier circuit of the embodiment of the invention includes an amplifier and a matching circuit. The matching circuit is coupled to the amplifier. The matching circuit includes the aforementioned impedance adjustment circuit.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A and FIG. 1B are schematic diagrams of amplifier circuits according to various embodiments of the invention.

FIG. 2A is a schematic diagram of an impedance adjustment circuit according to a first embodiment of the invention.

FIG. 2B is a schematic diagram of an impedance adjustment circuit according to a second embodiment of the invention.

FIG. 2C is a schematic diagram of an impedance adjustment circuit according to a third embodiment of the invention.

FIG. 3 is a schematic diagram of an impedance adjustment circuit according to a fourth embodiment of the invention.

FIG. 4A is a cross-sectional view of a metal-oxide-semiconductor capacitor MOScap and corresponding components in an impedance adjustment sub-circuit according to the first embodiment of the invention.

FIG. 4B is a cross-sectional view of the metal-oxide-semiconductor capacitor MOScap and corresponding components in the impedance adjustment sub-circuit according to the second embodiment of the invention.

FIG. 5A and FIG. 5B are schematic diagrams of switch circuits according to various embodiments of the invention.

FIG. 6A and FIG. 6B are schematic diagrams of the impedance adjustment sub-circuit and a capacitance value thereof of FIG. 4A according to the first embodiment of the invention.

FIG. 7 is a schematic diagram of an impedance adjustment circuit according to a fifth embodiment of the invention.

FIG. 8 is a schematic diagram of an impedance adjustment circuit according to the fifth embodiment of the invention.

FIG. 9 is a cross-sectional view of the metal-oxide-semiconductor capacitor MOScap and corresponding components in the impedance adjustment sub-circuit according to the fifth embodiment of the invention.

FIG. 10 is a schematic circuit diagram of a control circuit according to various embodiments of the invention.

### DESCRIPTION OF THE EMBODIMENTS

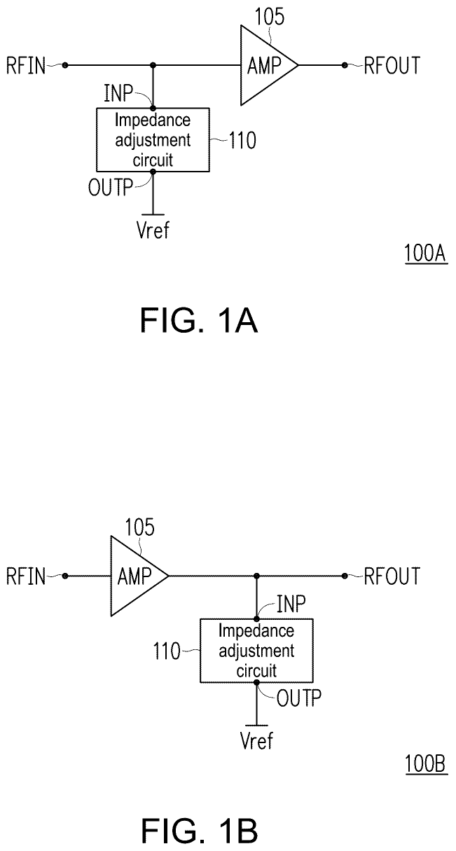

FIG. 1A and FIG. 1B are schematic diagrams of amplifier circuits 100A and 100B according to various embodiments of the invention. The amplifier circuits 100A and 100B of FIG. 1A and FIG. 1 B respectively include an amplifier AMP 105 and an impedance adjustment circuit 110 serving as a matching circuit.

The amplifier AMP 105 has a signal input terminal RFIN and a signal output terminal RFOUT. The amplifier AMP 105 of the embodiment may be a low-noise amplifier (LNA), and a user of the embodiment may adjust the type of the amplifier AMP 105 according to his or her needs. In an embodiment, the amplifier AMP 105 may be a power amplifier (PA).

The impedance adjustment circuit 110 includes an input terminal INP, an output terminal OUTP, and one or a plurality of impedance adjustment sub-circuits. In FIG. 1A, the input terminal INP of the impedance adjustment circuit 110 is coupled to the signal input terminal RFIN of the AMP 105. On the other hand, the input terminal INP of the impedance adjustment circuit 110 of FIG. 1B is coupled to the signal output terminal RFOUT of the AMP 105. The user of the embodiment may selectively couple the impedance adjustment circuit 110, which serves as a matching circuit, to the signal input terminal RFIN or the signal output terminal RFOUT of the AMP 105 according to their needs. The user of the embodiment may respectively couple different impedance adjustment circuits 110 to the signal input terminal RFIN or/and the signal output terminal RFOUT of the AMP 105 to serve as matching circuits. The user of the embodiment may also dispose the impedance adjustment circuit 110 at an input terminal or an output terminal of other types of circuits to serve as the corresponding matching circuit.

The impedance adjustment circuit 110 is configured to adjust an impedance of the signal input terminal RFIN or the signal output terminal RFOUT of the AMP 105. The user of the embodiment may provide a reference signal at the signal input terminal RFIN, and selectively adjust a capacitance value in the impedance adjustment circuit 110 according to a reflection coefficient or corresponding parameters of the reference signal. In an embodiment, a circuit designer may apply the impedance adjustment circuit 110 to other applications that require corresponding static/dynamic adjustment of circuits. In an embodiment, a frequency of the signal input terminal RFIN is inversely proportional to the capacitance value of the impedance adjustment circuit 110.

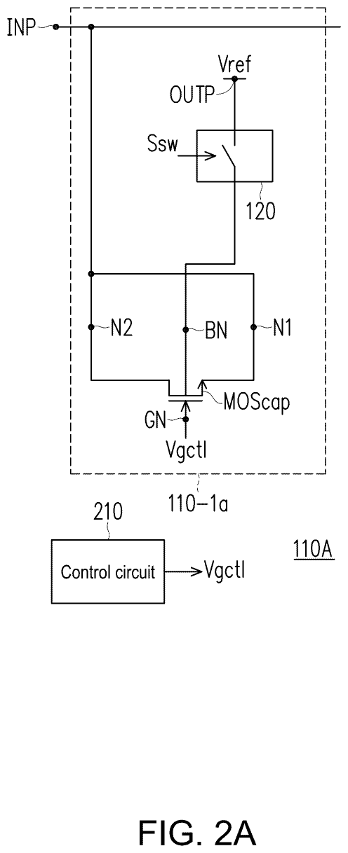

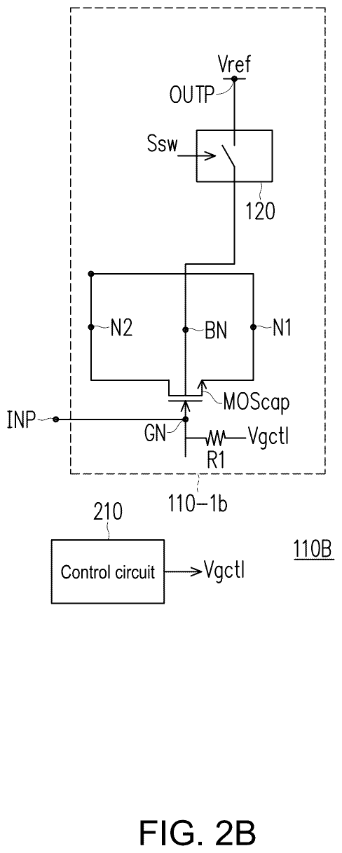

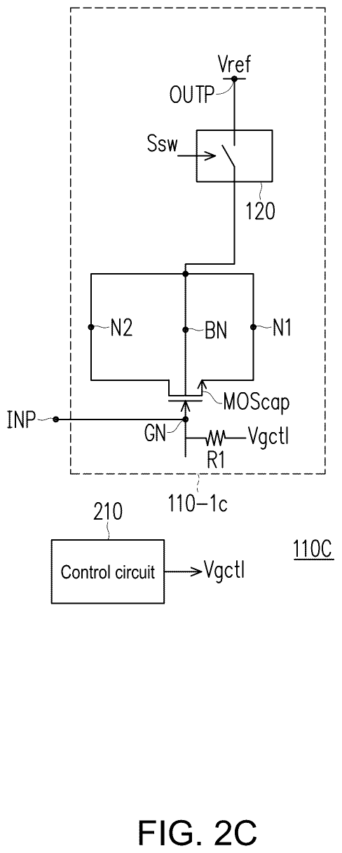

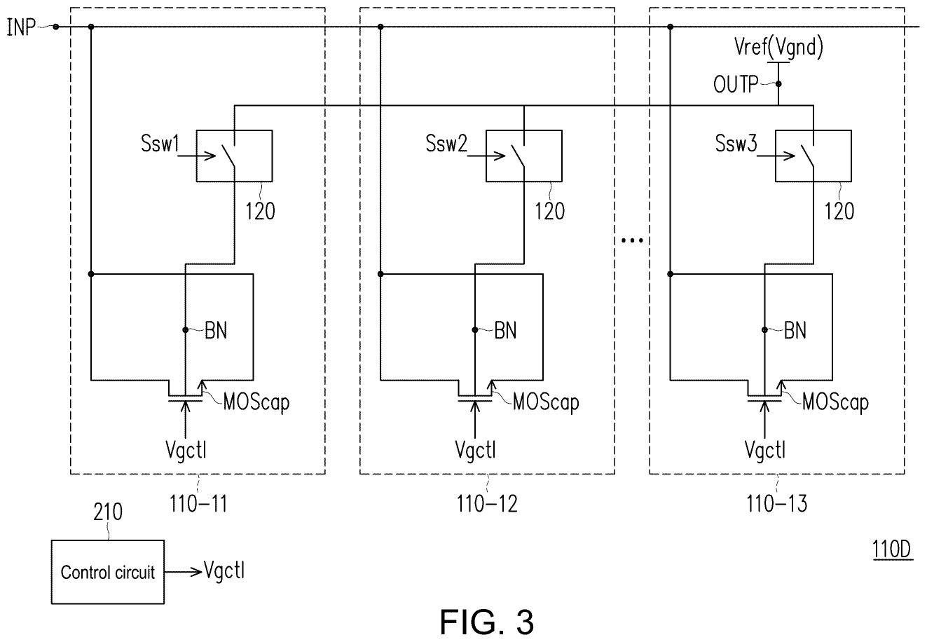

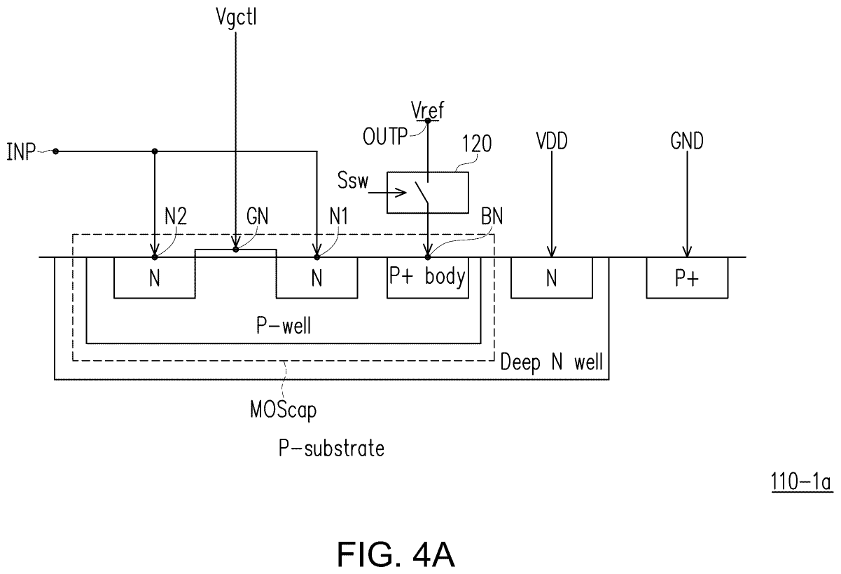

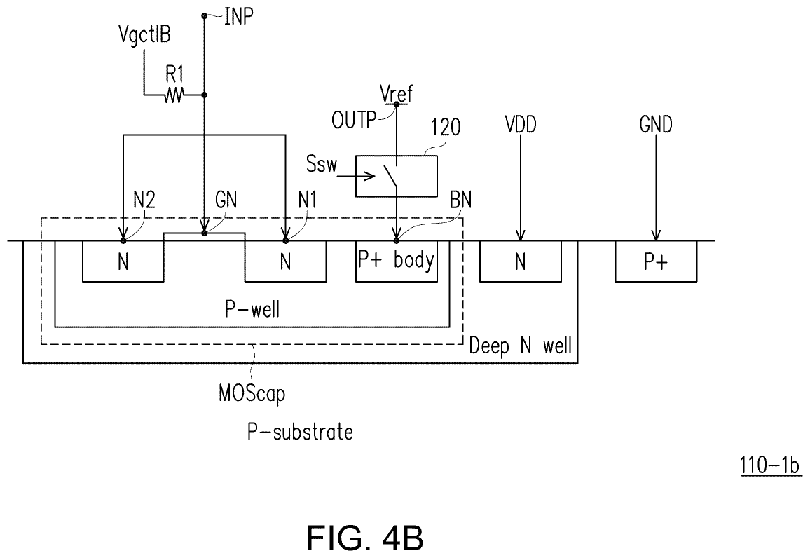

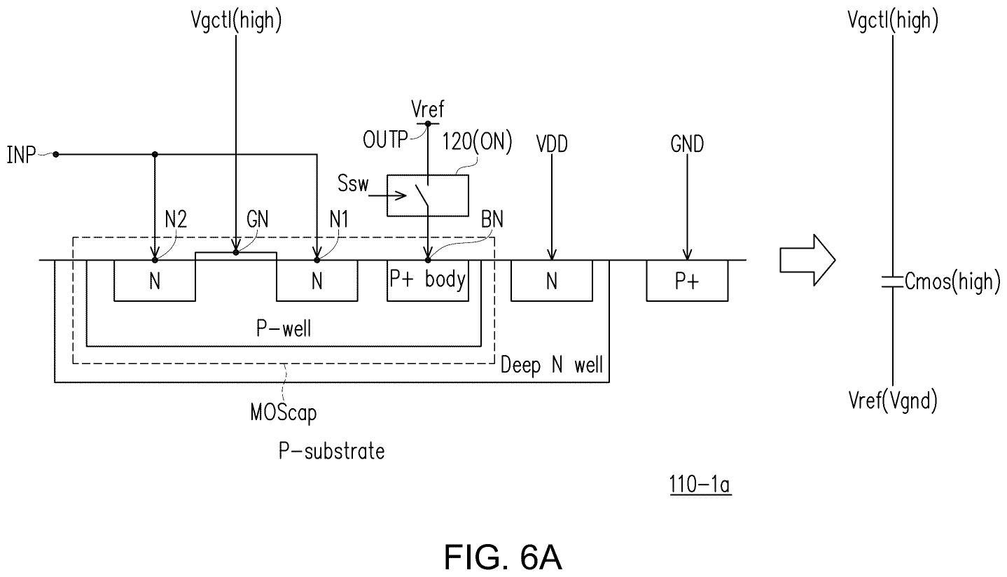

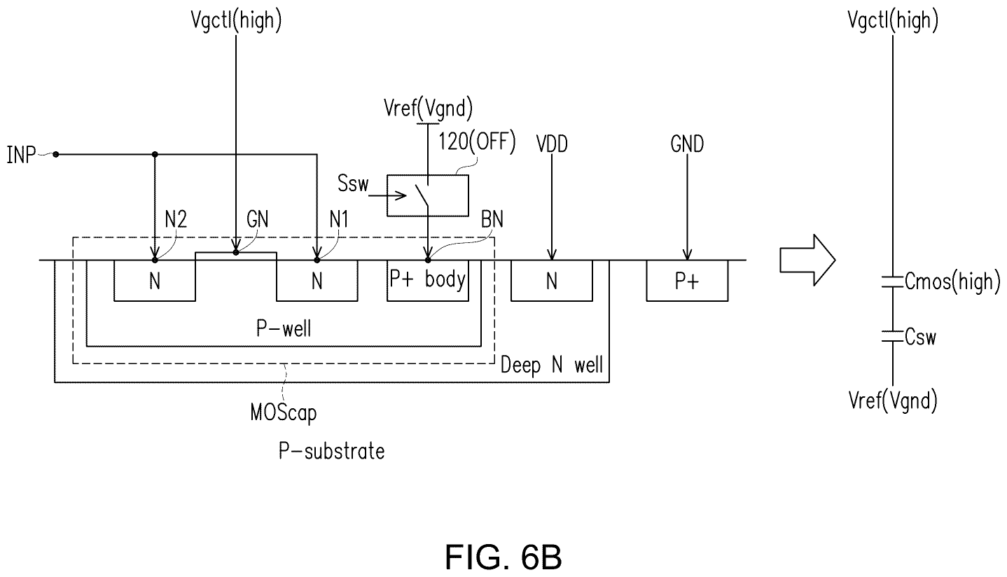

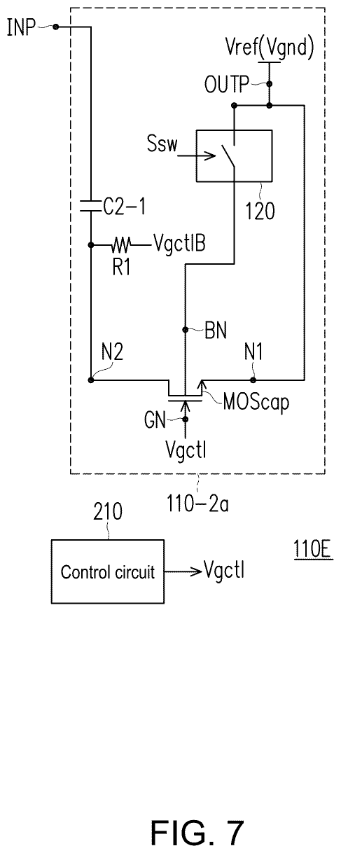

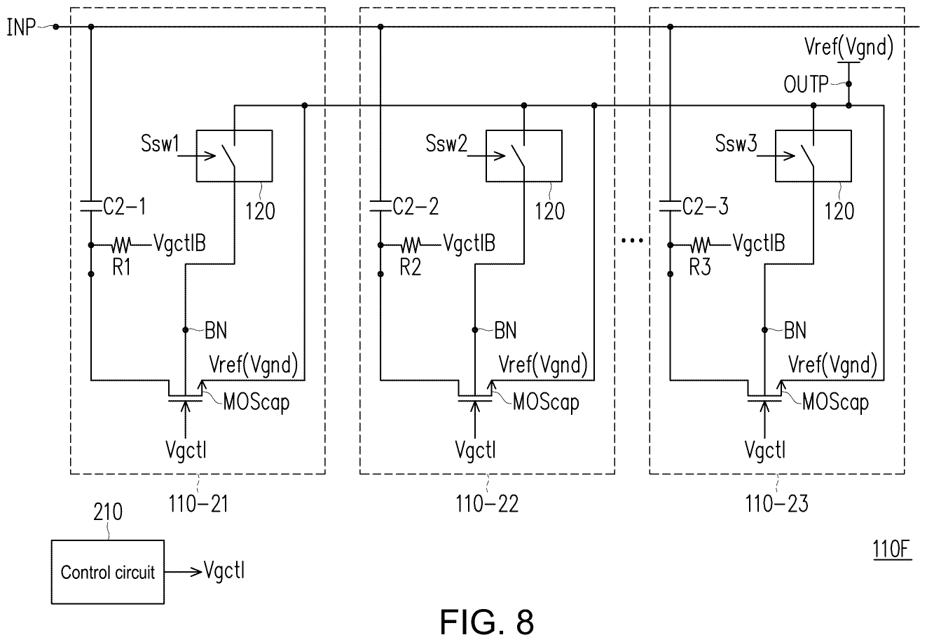

Various aspects of the impedance adjustment circuit 110 are described here through FIG. 2A to FIG. 2C, FIG. 3, FIG. 4A to FIG. 4B, FIG. 6A to FIG. 6B, and FIG. 7 to FIG. 8.

FIG. 2A is a schematic diagram of an impedance adjustment circuit 110A according to a first embodiment of the invention. The impedance adjustment circuit 110A includes an input terminal INP, an output terminal OUTP, and an impedance adjustment sub-circuit 110-1a. The impedance adjustment sub-circuit 110-1a includes a metal-oxide-semiconductor capacitor MOScap and a switch circuit 120. The metal-oxide-semiconductor capacitor MOScap in the embodiment is an N-type transistor. The user of the embodiment may also use a P-type transistor to implement the metal-oxide-semiconductor capacitor MOScap.

The metal-oxide-semiconductor capacitor MOScap includes a first terminal N1 (for example, source terminal), a second terminal N2 (for example, drain terminal), a control terminal GN (for example, gate terminal), and a base terminal BN. The control terminal GN of the metal-oxide-semiconductor capacitor MOScap receives a control signal Vgctl. The second terminal N2 of the embodiment is coupled to the input terminal INP. The first terminal N1 and the second terminal N2 of the embodiment are coupled to each other. In the embodiment, the first terminal N1, the second terminal N2 and the input terminal INP may be directly coupled.

A control terminal of the switch circuit 120 receives a switch control signal Ssw. The base terminal BN is coupled to the output terminal OUTP through the switch circuit 120. The impedance adjustment circuit 110A further includes a control circuit 210 for generating the control signal Vgctl. Specifically, one end of the switch circuit 120 is directly coupled to the base terminal BN, and the other end of the switch circuit 120 is directly coupled to the output terminal OUTP. The output terminal OUTP of the embodiment may be a reference voltage terminal. The reference voltage terminal provides a reference voltage Vref (for example, ground voltage) to the other end of the switch circuit 120. When the control signal Vgctl is enabled, the embodiment of the invention changes a capacitance value of the impedance adjustment sub-circuit 110-1a by changing the switch control signal Ssw. In other words, by changing the switch control signal Ssw, a capacitance value of the switch circuit 120 itself may be changed, thereby further changing the capacitance value of the impedance adjustment sub-circuit 110-1a. The “capacitance value of the switch circuit 120 itself” described in the embodiment may be a discrete capacitor, or a switched-capacitor. Namely, the capacitance value of the switch circuit 120 itself may be switched to have a discretely varied capacitance value.

The capacitance value of the impedance adjustment sub-circuit 110-1a is determined based on a capacitance value between the gate terminal GN and the base terminal BN in the metal-oxide-semiconductor capacitor MOScap, and the capacitance value of the switch circuit 120 located between the base terminal BN and the output terminal OUTP. Since there is the switch circuit 120 between the base terminal BN and the output terminal OUTP, and whether the switch circuit 120 is turned on or not is controlled by the switch control signal Ssw to correspondingly change the capacitance value of the switch circuit 120 itself, the capacitance value of the impedance adjustment sub-circuit 110-1a may be changed by the switch control signal Ssw.

FIG. 2B is a schematic diagram of an impedance adjustment circuit 110B according to a second embodiment of the invention. A difference between the impedance adjustment circuit 110B of FIG. 2B and the impedance adjustment circuit 110A of FIG. 2A is that the control terminal GN of the metal-oxide-semiconductor capacitor MOScap in an impedance adjustment sub-circuit 110-1b is coupled to the input terminal INP and receives an inverted control signal VgtlB through a bias resistor R1. The impedance adjustment circuit 110B of FIG. 2B further includes the bias resistor R1. One end of the bias resistor R1 is coupled to the control terminal GN of the metal-oxide-semiconductor capacitor MOScap, and the other end of the bias resistor R1 receives the inverted control signal VgtlB. In addition, the second terminal N2 and the first terminal N1 are not coupled to the input terminal INP.

Therefore, when the control signal Vgctl is enabled, the capacitance value of the impedance adjustment sub-circuit 110-1n is determined based on the capacitance value between the control terminal GN and the base terminal BN in the metal-oxide-semiconductor capacitor MOScap, and the capacitance value of the switch circuit 120. The embodiment of the invention changes the capacitance value of the switch circuit 120 by changing the switch control signal Ssw, thereby changing the capacitance value of the impedance adjustment sub-circuit 110-1b.

FIG. 2C is a schematic diagram of an impedance adjustment circuit 110C according to a third embodiment of the invention. A difference between the impedance adjustment circuit 110C of FIG. 2C and the impedance adjustment circuit 110B of FIG. 2B is that the first terminal N1, the second terminal N2 and the base terminal BN of the metal-oxide-semiconductor capacitor MOScap in the impedance adjustment sub-circuit 110-1c are all coupled to each other. Therefore, when the control signal Vgctl is enabled, the capacitance value of the impedance adjustment sub-circuit 110-1c is determined based on the capacitance value between the control terminal GN and the base terminal BN in the metal-oxide-semiconductor capacitor MOScap, and the capacitance value of the switch circuit 120. The embodiment of the invention changes the capacitance value of the switch circuit 120 by changing the switch control signal Ssw, thereby changing the capacitance value of the impedance adjustment sub-circuit 110-1c.

FIG. 3 is a schematic diagram of an impedance adjustment circuit 110D according to a fourth embodiment of the invention. In addition to the input terminal INP and the output terminal OUTP, the impedance adjustment circuit 110D further includes at least two impedance adjustment sub-circuits, for example, one impedance adjustment sub-circuit (for example, an impedance adjustment sub-circuit 110-11 of FIG. 3) and another impedance adjustment sub-circuit. circuit (for example, impedance adjustment sub-circuit 110-12 of FIG. 3). Any impedance adjustment sub-circuit 110-12 of FIG. 3 may include another metal-oxide-semiconductor capacitor MOScap and another switch circuit 120.

The impedance adjustment circuit 110D of FIG. 3 presents at least three impedance adjustment sub-circuits 110-11 to 110-13, and the user of the embodiment may adjust the number of the impedance adjustment sub-circuits according to their needs. The circuit structures of the impedance adjustment sub-circuit 110-11 to 110-13 of FIG. 3 are the same as that of the impedance adjustment sub-circuit 110-1a of FIG. 2A. The user of the embodiment may use the circuit structure of one of the impedance adjustment sub-circuits 110-1a to 110-1c of FIG. 2A to FIG. 2C or a combination thereof to implement the circuit structure of the impedance adjustment sub-circuit 110-11 to 110-13 according to their needs. The embodiment may provide independent switch control signals Ssw1-Ssw3 to the impedance adjustment sub-circuits 110-11 to 110-13 of FIG. 3, so that the impedance adjustment sub-circuits 110-11 to 110-13 of FIG. 3 respectively present the capacitance values set through the switch control signals Ssw1-Ssw3. The overall capacitance value of the impedance adjustment circuit 110D of FIG. 3 is based on a value of the capacitance values of the impedance adjustment sub-circuits 110-11 to 110-13 of FIG. 3 after parallel connection. Namely, the overall capacitance value of the impedance adjustment circuit 110D of FIG. 3 a sum of the capacitance values of the impedance adjustment sub-circuits 110-11 to 110-13 of FIG. 3.

FIG. 4A is a cross-sectional view of the metal-oxide-semiconductor capacitor MOScap and corresponding components in the impedance adjustment sub-circuit 110-1a according to the first embodiment of the invention. The metal-oxide-semiconductor capacitor MOScap and the switch circuit 120 of the impedance adjustment sub-circuit 110-1a are shown in FIG. 4A, and a coupling method of each component of the impedance adjustment sub-circuit 110-1a in FIG. 4A is the same as that in FIG. 2A. In FIG. 4A, “P-well” represents a P-type well layer, “Deep N well” represents a deep N-type well layer, and “P-substrate” represents a P-type substrate layer. VDD represents a system voltage terminal, and GND represents a ground terminal.

FIG. 4B is a cross-sectional view of the metal-oxide-semiconductor capacitor MOScap and corresponding components in the impedance adjustment sub-circuit 110-1b according to the second embodiment of the invention. The metal-oxide-semiconductor capacitor MOScap, the switch circuit 120 and the bias resistor R1 of the impedance adjustment sub-circuit 110-1b are shown in FIG. 4B, and the coupling method of each component of the impedance adjustment sub-circuit 110-1b in FIG. 4B is the same as that in FIG. 2B.

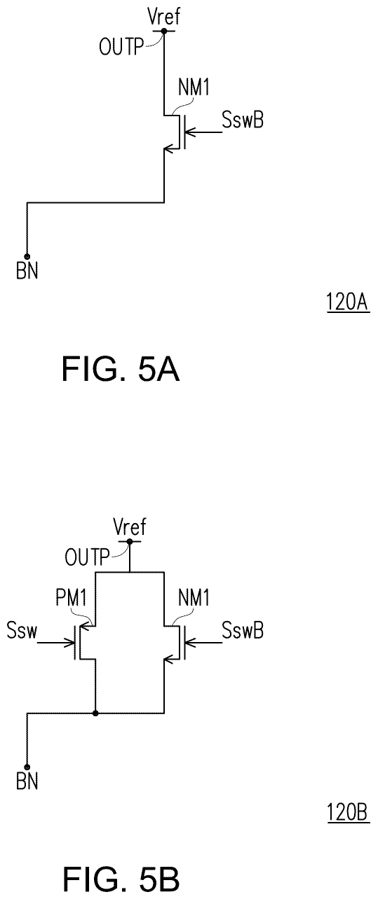

FIG. 5A and FIG. 5B are schematic diagrams of switch circuits 120A and 120B according to various embodiments of the invention. The switch circuit 120 in each embodiment of the invention may be selectively implemented by the switch circuits 120A and 120B of FIG. 5A and FIG. 5B. The user of the embodiment may also implement the switch circuit 120 in each embodiment by using other types of switch circuits.

The switch circuit 120A of FIG. 5A includes a switch transistor NM1. A first terminal (for example, source terminal) of the switch transistor NM1 is coupled to the base terminal BN of the metal-oxide-semiconductor capacitor MOScap. A second terminal (for example, drain terminal) of the switch transistor NM1 is coupled to the output terminal OUTP. A control terminal (for example, gate terminal) of the switch transistor NM1 receives an inverted switch control signal SswB. Based on the circuit structure of FIG. 5A, a conduction state of the switch circuit 120A may be changed by changing the inverted switch control signal SswB, thereby changing a capacitance value of the switch circuit 120A itself. The switch transistor NM1 of the embodiment may be an N-type transistor. In an embodiment, the switch transistor of FIG. 5A may be a P-type transistor, and a control terminal of the P-type transistor receives a forward switch control signal.

Compared with FIG. 5A, the switch circuit 120B of FIG. 5B further includes a switch transistor PM1 in addition to the switch transistor NM1. A first terminal (for example, source terminal) of the switch transistor PM1 is coupled to the output terminal OUTP. A second terminal (for example, drain terminal) of the switch transistor PM1 is coupled to the base terminal BN of the metal-oxide-semiconductor capacitor MOScap. A control terminal (for example, gate terminal) of the switch transistor PM1 receives the switch control signal Ssw. Based on the circuit structure of FIG. 5B, by changing the switch control signal Ssw, the inverted switch control signal SswB may be correspondingly changed, so as to change the capacitance value of the switch circuit 120A itself. In the embodiment, the switch transistor NM1 may be an N-type transistor, and the control terminal of the N-type transistor receives an inverted switch control signal, and the switch transistor PM1 may be a P-type transistor, and the control terminal of the P-type transistor receives the forward switch control signal.

FIG. 6A and FIG. 6B are schematic diagrams of the impedance adjustment sub-circuit 110-1a and a capacitance value thereof of FIG. 4A according to the first embodiment of the invention. Referring to FIG. 6A, when the control signal Vgctl is enabled (for example, at logic “high”) and the switch circuit 120 is controlled by the switch control signal Ssw and is turned on to couple the reference voltage Vref (for example, ground voltage Vgnd) on the output terminal OUTP to the base terminal BN of the metal-oxide-semiconductor capacitor MOScap, the two ends of the switch circuit 120 are conducted and have no capacitance values. Therefore, an equivalent capacitance value of the impedance adjustment sub-circuit 110-1a is a capacitance value Cmos (high) between an oxide layer on the gate terminal GN and a P-type doped layer (such as “P+body”) on the base terminal BN of the metal-oxide-semiconductor capacitor MOScap, as shown in a right part of FIG. 6A.

On the other hand, the capacitance value between the oxide layer on the gate terminal GN and the P-type doped layer (such as “P+body”) on the base terminal BN of the metal-oxide-semiconductor capacitor MOScap may have a corresponding capacitance value based on enabling (for example, logic “high”) or disabling (for example, logic “low”) of the control signal Vgctl. The equivalent capacitance values of the metal-oxide-semiconductor capacitor MOScap are referred to as a capacitance value Cmos (high) (when the control signal Vgctl is enabled) and a capacitance value Cmos (low) (when the control signal Vgctl is disabled). Therefore, if the control signal Vgctl is disabled and the switch circuit 120 is turned on, the equivalent capacitance value of the impedance adjustment sub-circuit 110-1a is the capacitance value Cmos (low).

Referring to FIG. 6B, when the control signal Vgctl is enabled (for example, logic “high”) and the switch circuit 120 is controlled by the switch control signal Ssw and turned off, the two ends of the switch circuit 120 are cut off so that the switch circuit 120 itself has a capacitance value Csw. Therefore, the equivalent capacitance value of the impedance adjustment sub-circuit 110-1a is an equivalent capacitance value formed after a series connection of the capacitance value Cmos between the oxide layer on the gate terminal GN and the P-type doped layer (such as “P+body”) on the base terminal BN of the metal-oxide-semiconductor capacitor MOScap and the capacitance value Csw of the switch circuit 120, as shown in a right part of FIG. 6B.

On the other hand, if the control signal Vgctl is disabled and the switch circuit 120 is turned off, the equivalent capacitance value of the impedance adjustment sub-circuit 110-1a is an equivalent capacitance value obtained after a series connection of the “capacitance value Cmos (low)” and the “capacitance value Csw of the switch circuit 120”.

FIG. 7 is a schematic diagram of an impedance adjustment circuit 110E according to a fifth embodiment of the invention. The impedance adjustment circuit 110E includes an input terminal INP, an output terminal OUTP, and an impedance adjustment sub-circuit 110-2a. A difference between the impedance adjustment sub-circuit 110-2a in FIG. 7 and the impedance adjustment sub-circuit 110-1a in FIG. 2A is that the impedance adjustment sub-circuit 110-2a in FIG. 7 further includes a matching capacitor C2-1 and a bias resistor R1. Moreover, in the embodiment, the first terminal N1 of the metal-oxide-semiconductor capacitor MOScap is coupled to the output terminal OUTP, but not to the second terminal N2 or the input terminal INP.

The matching capacitor of the embodiment may be coupled between the input terminal INP and one of the first terminal N1 and the second terminal N2 of the metal-oxide-semiconductor capacitor MOScap. For example, in FIG. 7, the matching capacitor C2-1 is disposed between the input terminal INP and the second terminal N2 of the metal-oxide-semiconductor capacitor MOScap. In other embodiments, the matching capacitor may be disposed between the input terminal INP and the first terminal N1 of the metal-oxide-semiconductor capacitor MOScap of FIG. 2A, or the matching capacitor may be disposed between the input terminal INP and the second terminal N2 of the metal-oxide-semiconductor capacitor MOScap of FIG. 2A.

A first terminal of the bias resistor R1 is coupled to one terminal of the metal-oxide-semiconductor capacitor MOScap (for example, the first terminal N1), and a second terminal of the bias resistor R1 receives an inverted control signal VgctlB. In other embodiments, the first terminal of the bias resistor may be coupled to one of the first terminal and the second terminal of the metal-oxide-semiconductor capacitor MOScap. When the control signal Vgctl is enabled, in the embodiment of the invention, the capacitance value of the impedance adjustment sub-circuit 110-2a is changed by changing the switch control signal Ssw. In other words, by changing the switch control signal Ssw, the capacitance value of the switch circuit 120 itself may be changed, thereby further changing the capacitance value of the impedance adjustment sub-circuit 110-2a. In an embodiment, the impedance adjustment circuit 110E may include at least one of the matching capacitor C2-1 and the bias resistor R1.

FIG. 8 is a schematic diagram of an impedance adjustment circuit 110F according to the fifth embodiment of the invention. In addition to the input terminal INP and the output terminal OUTP, the impedance adjustment circuit 110F further includes at least two impedance adjustment sub-circuits. The impedance adjustment circuit 110F in FIG. 8 presents at least three impedance adjustment sub-circuits 110-21 to 110-23, and the user of the embodiment may adjust the number of the impedance adjustment sub-circuits according to their needs. The circuit structures of the impedance adjustment sub-circuit 110-11 to 110-13 in FIG. 3 are the same as that of the impedance adjustment sub-circuit 110-2a in FIG. 7.

The user of the embodiment may implement the circuit structures of the impedance adjustment sub-circuit 110-21 to 110-23 of FIG. 8 by one of the impedance adjustment sub-circuit 110-1a to 110-1c, 110-2a or a combination thereof in FIG. 2A to FIG. 2C and FIG. 7 according to their needs. The embodiment may provide independent switch control signals Ssw1-Ssw3 to the impedance adjustment sub-circuits 110-21 to 110-23 of FIG. 8 respectively, so that the impedance adjustment sub-circuits 110-21 to 110-33 of FIG. 8 respectively present capacitance values set by the switch control signals Ssw1-Ssw3. The corresponding values of the matching capacitors C2-1 to C2-3 and the bias resistors R1 to R3 in the impedance adjustment sub-circuits 110-21 to 110-33 of FIG. 8 may be adjusted according to the needs of the user that applies the embodiment and actual circuit design requirements. An overall capacitance value of the impedance adjustment circuit 110F of FIG. 8 is based on a parallel connection of the capacitance values of the impedance adjustment sub-circuit 110-21 to 110-23 of FIG. 8. Namely, an overall capacitance value of the impedance adjustment sub-circuits 110-21 to 110-23 of FIG. 8 is a sum of the capacitance values of the impedance adjustment sub-circuit 110-21 to 110-23 of FIG. 8.

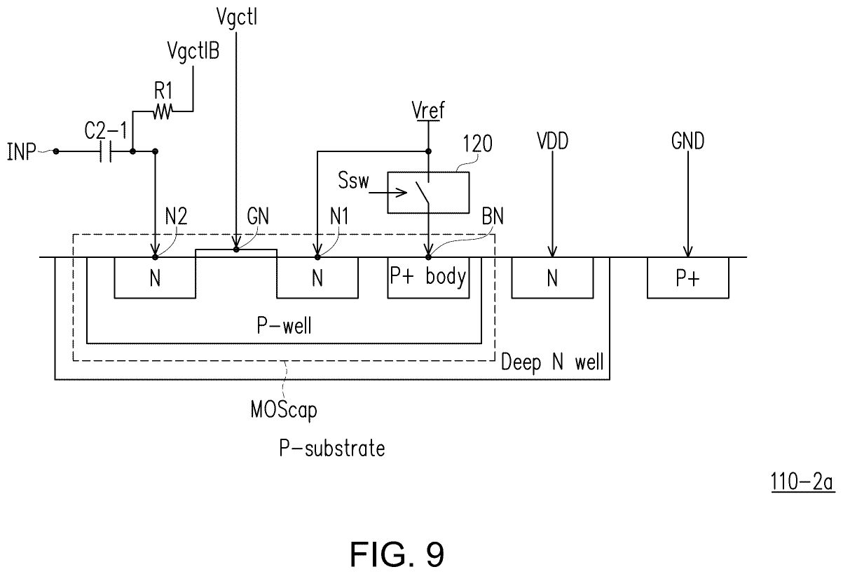

FIG. 9 is a cross-sectional view of the metal-oxide-semiconductor capacitor MOScap and corresponding components in the impedance adjustment sub-circuit 110-2a according to the fifth embodiment of the invention. The metal-oxide-semiconductor capacitor MOScap and the switch circuit 120 of the impedance adjustment sub-circuit 110-2a are shown in FIG. 7, and a coupling method of each component of the impedance adjustment sub-circuit 110-2a of FIG. 9 is the same as that in FIG. 7.

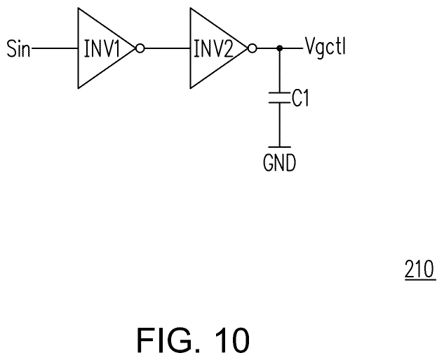

FIG. 10 is a schematic circuit diagram of the control circuit 210 according to various embodiments of the invention. The control circuit 210 in FIG. 10 is one example of the control circuit 210 in various embodiments of the invention. The user of the embodiment may choose a suitable circuit structure to implement the control circuit 210 according to their needs. The control circuit 210 of FIG. 10 includes inverters INV1, INV2 and a control capacitor C1. An input terminal of the inverter INV1 receives an input signal Sin and serves as the input terminal of the control circuit 210. An output terminal of the inverter INV1 is coupled to an input terminal of the inverter INV2. A first terminal of the control capacitor C1 is coupled to an output terminal of the inverter INV2 and serves as an output terminal of the control circuit 210. The output terminal of the control circuit 210 is configured to generate the control signal Vgctl. The control capacitor C1 is configured to stabilize a voltage of the output terminal of the control circuit 210.

In an embodiment, the control circuit 210 may further include a digital control circuit for controlling states of the control signal Vgctl and the switch control signal Ssw. Namely, the control circuit 210 may simultaneously control the states of the control signal Vgctl and the switch control signal Ssw to adjust a magnitude of the capacitance value. For example, the circuit diagram of FIG. 2A may achieve four capacitance values by controlling the states of the control signal Vgctl and the switch control signal Ssw. When a control state is a state one, the minimum capacitance value may be obtained; when the control state is a state four, the maximum capacitance value may be obtained. On the other hand, when the control state is a state two or a state three, the capacitance values obtained respectively depend on size, and may be determined by designer choice of a transistor size.

TABLE ONE

| | State one | State two | State three | State four |
|---|---|---|---|---|
| Control signal | Logic low | Logic low | Logic high | Logic high |
| (Vgctl) | | | | |
| Switch control | Logic low | Logic high | Logic low | Logic high |
| signal (Ssw) | | | | |
| Capacitance | Minimum | Medium | Medium | Maximum |
| value | | | | |

In an embodiment, when a frequency of the signal input terminal RFIN is relatively high, the control state may be set to the state one; conversely, when the frequency of the signal input terminal RFIN is relatively low, the control state may be set to the state four to maintain better reflection coefficient.

In summary, in the impedance adjustment circuit and amplifier circuit of the embodiments of the invention, a switch circuit is added between the base terminal and the output terminal (such as ground terminal) of the metal-oxide-semiconductor capacitor in each impedance adjustment sub-circuit, and through the control voltage of the gate terminal of the metal-oxide-semiconductor capacitor and the conduction of the switch circuit, the capacitance value in the impedance adjustment circuit may have multi-stage changes. Therefore, the impedance adjustment circuit and the amplifier circuit of the embodiments of the invention may adaptively adjust the capacitance value of the impedance adjustment circuit for different situations, thereby reducing noise in the input signal of the amplifier circuit and reducing the loss of the amplified signal to increase a gain thereof. The invention provides an impedance adjustment circuit and an amplifier circuit, which may adjust the capacitance value of the impedance adjustment circuit in multiple stages and increase a bandwidth during signal processing.

What is claimed is:

1. An impedance adjustment circuit, adapted to provide different capacitance values, comprising:
an input terminal;
an output terminal; and
an impedance adjustment sub-circuit, comprising:
a metal-oxide-semiconductor capacitor, comprising a first terminal, a second terminal, a control terminal, and a base terminal, wherein the second terminal is coupled to the input terminal, and the control terminal of the metal-oxide-semiconductor capacitor receives a control signal; and
a switch circuit, having a control terminal receiving a switch control signal, wherein the base terminal of the metal-oxide-semiconductor capacitor is coupled to the output terminal through the switch circuit, and a capacitance value of the impedance adjustment sub-circuit is changed by changing the switch control signal.

2. The impedance adjustment circuit as claimed in claim 1, wherein a capacitance value of the switch circuit is changed by changing the switch control signal.

3. The impedance adjustment circuit as claimed in claim 1, wherein the first terminal of the metal-oxide-semiconductor capacitor is coupled to the input terminal.

4. The impedance adjustment circuit as claimed in claim 3, further comprising:
another impedance adjustment sub-circuit, comprising:
another metal-oxide-semiconductor capacitor, comprising a first terminal, a second terminal, a control terminal, and a base terminal, wherein the first terminal and the second terminal are coupled to the input terminal, and the control terminal of the another metal-oxide-semiconductor capacitor receives a control signal; and
another switch circuit, having a control terminal receives a switch control signal, wherein by changing the switch control signal, the base terminal of the another metal-oxide-semiconductor capacitor is selectively coupled to the output terminal.

5. The impedance adjustment circuit as claimed in claim 1, wherein the first terminal of the metal-oxide-semiconductor capacitor is coupled to the output terminal.

6. The impedance adjustment circuit as claimed in claim 5, further comprising:
another impedance adjustment sub-circuit, comprising:
another metal-oxide-semiconductor capacitor, comprising a first terminal, a second terminal, a control terminal, and a base terminal, wherein the first terminal is coupled to the output terminal, the second terminal is coupled to the input terminal, and the control terminal of the another metal-oxide-semiconductor capacitor receives a control signal; and
another switch circuit, having a control terminal receiving a switch control signal, wherein the base terminal of the another metal-oxide-semiconductor capacitor is coupled to the output terminal through the switch circuit, and by changing the switch control signal, the capacitance value of the impedance adjustment sub-circuit is changed.

7. The impedance adjustment circuit as claimed in claim 1, wherein the switch circuit is a discrete capacitor.

8. The impedance adjustment circuit as claimed in claim 7, wherein the switch circuit comprises:
a first switch transistor, having a first terminal coupled to the base terminal of the metal-oxide-semiconductor capacitor, a second terminal coupled to the output terminal, and a control terminal coupled to the switch control signal.

9. The impedance adjustment circuit as claimed in claim 7, wherein the switch circuit comprises:
a first switch transistor, having a first terminal coupled to the base terminal of the metal-oxide-semiconductor capacitor, a second terminal coupled to the output terminal, and a control terminal coupled to the switch control signal; and
a second switch transistor, having a first terminal coupled to the output terminal, a second terminal coupled to the base terminal of the metal-oxide-semiconductor capacitor, and a control terminal coupled to the inverted switch control signal.

10. The impedance adjustment circuit as claimed in claim 1, wherein the impedance adjustment sub-circuit further comprises:
a matching capacitor, wherein the matching capacitor is coupled between the input terminal and one of the first terminal and the second terminal of the metal-oxide-semiconductor capacitor.

11. The impedance adjustment circuit as claimed in claim 1, wherein the impedance adjustment sub-circuit further comprises:
a bias resistor, having a first terminal coupled to one of the first terminal and the second terminal of the metal-oxide-semiconductor capacitor, and a second terminal receiving the inverted control signal.

12. An impedance adjustment circuit, configured to provide different capacitance values, comprising:
an input terminal;
an output terminal; and
an impedance adjustment sub-circuit, comprising:
a metal-oxide-semiconductor capacitor, comprising a first terminal, a second terminal, a control terminal, and a base terminal, wherein the control terminal of the metal-oxide-semiconductor capacitor is coupled to the input terminal; and
a switch circuit, having a control terminal receiving a switch control signal, wherein the base terminal of the metal-oxide-semiconductor capacitor is coupled to the output terminal through the switch circuit, and a capacitance value of the impedance adjustment sub-circuit is changed by changing the switch control signal.

13. The impedance adjustment circuit as claimed in claim 12, wherein the first terminal of the metal-oxide-semiconductor capacitor is coupled to the second terminal of the metal-oxide-semiconductor capacitor.

14. The impedance adjustment circuit as claimed in claim 13, wherein the first terminal of the metal-oxide-semiconductor capacitor is coupled to the base terminal of the metal-oxide-semiconductor capacitor.

15. An amplifier circuit, comprising:
an amplifier; and
a matching circuit, coupled to the amplifier,
wherein the matching circuit comprises the impedance adjustment circuit as claimed in claim 1.

16. The amplifier circuit as claimed in claim 15, wherein a capacitance value of the switch circuit is changed by changing the switch control signal.

17. The amplifier circuit as claimed in claim 15, wherein the first terminal of the metal-oxide-semiconductor capacitor is coupled to the input terminal.

18. The amplifier circuit as claimed in claim 17, the matching circuit further comprising:
another impedance adjustment sub-circuit, comprising:
another metal-oxide-semiconductor capacitor, comprising a first terminal, a second terminal, a control terminal, and a base terminal, wherein the first terminal and the second terminal are coupled to the input terminal, and the control terminal of the another metal-oxide-semiconductor capacitor receives a control signal; and
another switch circuit, having a control terminal receives a switch control signal, wherein by changing the switch control signal, the base terminal of the another metal-oxide-semiconductor capacitor is selectively coupled to the output terminal.

19. The amplifier circuit as claimed in claim 15, wherein the first terminal of the metal-oxide-semiconductor capacitor is coupled to the output terminal.

20. The amplifier circuit as claimed in claim 19, the matching circuit further comprising:
another impedance adjustment sub-circuit, comprising:
another metal-oxide-semiconductor capacitor, comprising a first terminal, a second terminal, a control terminal, and a base terminal, wherein the first terminal is coupled to the output terminal, the second terminal is coupled to the input terminal, and the control terminal of the another metal-oxide-semiconductor capacitor receives a control signal; and
another switch circuit, having a control terminal receiving a switch control signal, wherein the base terminal of the another metal-oxide-semiconductor capacitor is coupled to the output terminal through the switch circuit, and by changing the switch control signal, the capacitance value of the impedance adjustment sub-circuit is changed.
